(19) United States
(12) Patent Application Publication
(10) Pub. No.: US 2012/0118364 A1
(43) Pub. Date: May 17, 2012

(54) SOLAR CELL

(75) Inventors: Juhong YANG, Changwon-si (KR); Jinah KIM, Changwon-si (KR); Jeongbeom NAM, Changwon-si (KR); Indo CHUNG, Changwon-si (KR); Seunghwan SHIM, Changwon-si (KR); IIhyoung JUNG, Changwon-si (KR); Hyungjin KWON, Changwon-si (KR)

(73) Assignee: LG ELECTRONICS INC., Seoul (KR)

(21) Appl. No.: 13/296,059

(22) Filed: Nov. 14, 2011

(30) Foreign Application Priority Data
Nov. 15, 2010 (KR) 10-2010-0113371

(51) Int. Cl. H01L 31/0352; H01L 31/0232

(52) U.S. Cl. 136/255

(57) ABSTRACT

A solar cell includes a silicon semiconductor substrate including a plurality of concave portions formed at a first surface thereof; an emitter layer formed at the first surface of the silicon semiconductor substrate having the plurality of concave portions; an antireflection layer formed on the emitter layer; and a front electrode layer connected to the emitter layer by penetrating through the antireflection layer. The front electrode layer is formed on a flat surface between the plurality of concave portions and has a finger matrix shape. Accordingly, an area of the concave portions effectively absorbing sun light can increase, and the reduction of fill factor can be reduced or prevented by a short horizontal migration length of electrons.

### CROSS-REFERENCE TO RELATED APPLICATION

This application claims priority to and the benefit of Korean Patent Application No. 10-2010-0113371, filed on Nov. 15, 2010 in the Korean Intellectual Property Office, the disclosure of which is incorporated herein by reference.

### BACKGROUND OF THE INVENTION

1. Field of the Invention

Embodiments of the invention relate to a solar cell, and more particularly, to a solar cell having a short horizontal migration length of electrons in an emitter layer.

2. Description of the Related Art

Recently, as it is expected that conventional energy resources such as petroleum and coal will be exhausted in the future, interest in alternative energy resources to replace the conventional energy resources has gradually increased. Among them, a solar cell is spotlighted as a new generation cell using a semiconductor device for directly converting solar energy into electric energy.

In other words, a solar cell is a device converting solar energy into electric energy by using a photovoltaic effect. Depending on the material, solar cells can be classified into a silicon solar cell, a thin-film solar cell, a dye-sensitized solar cell, and an organic polymer-type solar cell. For the solar cells, it is very important to improve the efficiency, which is related to a ratio of converting incident sun light into electric energy.

Accordingly, in order to improve the efficiency of the solar cell, for example, a texturing structure may be formed on a light incident surface where the sun light is incident so that surface reflectivity of the solar cell can be reduced. However, in this texturing structure, a horizontal migration length of electrons may be long, and thus, a fill factor may be reduced.

### SUMMARY OF THE INVENTION

The invention is directed to a solar cell having concave portions with a large area and having a short horizontal migration length of electrons in an emitter layer.

A solar cell according to an embodiment of the invention includes a silicon semiconductor substrate including a plurality of concave portions formed at a first surface thereof; an emitter layer formed at the first surface of the silicon semiconductor substrate having the plurality of concave portions; an antireflection layer formed on the emitter layer; and a front electrode layer connected to the emitter layer by penetrating through the antireflection layer. The front electrode layer is formed on a flat surface between the plurality of the concave portions and has a finger matrix shape. Accordingly, an area of the concave portions effectively absorbing the sun light can increase, and the reduction of fill factor can be reduced or prevented by a short horizontal migration length of electrons.

The plurality of the concave portions may include two adjacent concave portions that are adjacent to each other and have a minimum distance of separation of about 0.5 μm to about 1.5 μm.

Distances from a center to edges of the plurality of concave portions may be substantially the same in a plan view.

A ratio of a depth a maximum width of the at least one of the plurality of concave portions may be in a range of about 0.29 to about 0.87.

The plurality of concave portions may have a cross section of a semi-circular shape or a semi-elliptical shape.

The plurality of the concave portions may be arranged to constitute a honeycomb structure.

On the other hand, a solar cell according to another embodiment of the invention includes a silicon semiconductor substrate including a plurality of concave portions formed at a first surface thereof; an emitter layer formed at the silicon semiconductor substrate, and having a first portion that has a shape corresponding to the plurality of concave portions; an antireflection layer formed on the emitter layer, and having a portion that has a shape corresponding to the plurality of concave portions; and a front electrode layer formed on the antireflection layer. The front electrode layer includes a plurality holes corresponding to the plurality of concave portions, respectively, and is connected to the emitter layer by penetrating through the antireflection layer at a flat surface between the plurality of the concave portions.

The emitter layer may include the first portion formed at the plurality of concave portions, and a second portion connected to the front electrode layer and formed where the plurality of concave portions are not formed. The first portion may have a doping concentration smaller than that of the second portion.

The front electrode layer may have an aperture ratio of about 72% to about 98%.

### BRIEF DESCRIPTION OF THE DRAWINGS

FIG. 1 is a perspective view illustrating a solar cell according to an embodiment of the invention.

FIG. 2 is an enlarged view of a portion A of the solar cell in FIG. 1.

FIG. 3 is a graph illustrating current and fill factor according to distance between concave portions according embodiments of the invention.

FIG. 4 is a graph illustrating efficiency according to distance between concave portions according to embodiments of the invention.

FIG. 5 is a perspective view illustrating a solar cell according to another embodiment of the invention.

FIG. 6 is an enlarged view of a portion B of the solar cell in FIG. 5.

FIGS. 7 to 10 are cross-sectional views illustrating a method for manufacturing a solar cell according to an embodiment of the invention.

### DETAILED DESCRIPTION OF THE EMBODIMENTS

In the following description, it will be understood that when a layer (or film) is referred to as being “on” another layer or substrate, it can be directly on the other layer or substrate, or intervening layers may also be present. Further, it will be understood that when a layer is referred to as being “under” another layer, it can be directly under the other layer, and one or more intervening layers may also be present. In the figures, the dimensions of layers and regions are exaggerated or schematically illustrated, or some layers are omitted for clarity of illustration. In addition, the dimension of each part does not reflect an actual size thereof.

Hereinafter, embodiments of the invention will be described with reference to the accompanying drawings.

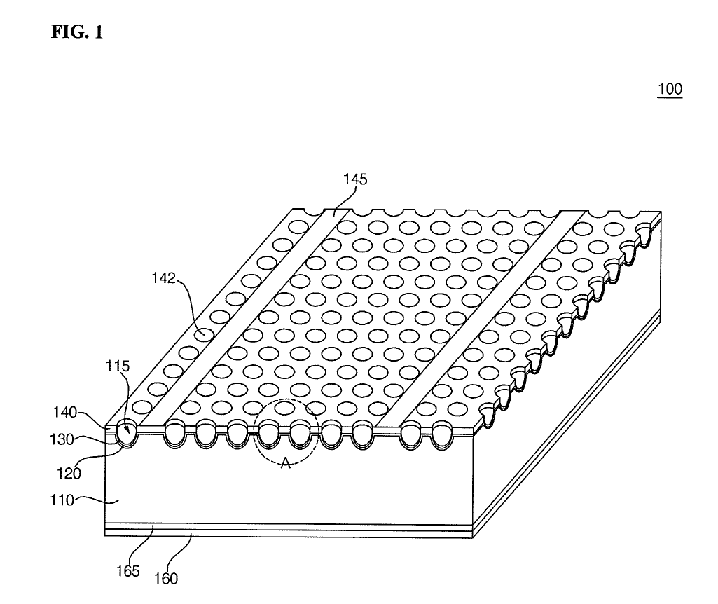

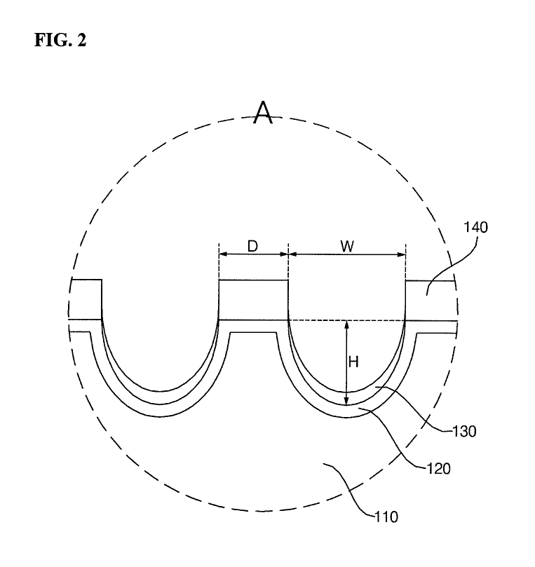

FIG. 1 is a perspective view illustrating a solar cell according to an embodiment of the invention, and FIG. 2 is an enlarged view of a portion A of the solar cell in FIG. 1. Referring to FIG. 1, a solar cell 100 according to an embodiment of the invention includes a substrate 110, an emitter layer 120, an antireflection layer 130, and a front electrode layer 140. In this instance, the substrate 110 includes a plurality of concave portions 115 formed at a surface (i.e., a light incident surface) thereof. The emitter layer 120 is formed on the surface of the substrate 110 having the concave portions 115. The antireflection layer 130 is formed on the emitter layer 120. The front electrode layer 140 is connected to the emitter layer 120 by penetrating through the antireflection layer 130.

The substrate 110 may include a semiconductor, such as silicon, and be doped with p-type impurities (for example, an impurity of group 3 elements such as B, Ga, and In) to have a p-type conductivity. The substrate 110 includes the concave portions 115 formed at one surface (i.e., a light incident surface) thereof. The concave portions 115 can reduce reflectivity of sun light incident to the solar cell 100, and thus, the amount of the sun light used for converting the solar energy to the electric energy can increase. Accordingly, the loss of the sun light at the solar cell 100 can decrease.

Referring to FIG. 2, the concave portion 115 has a symmetrical shape and distances from a center to edges are substantially the same in a plan view. Also, the distances from the center to the edges of the concave portion 115 in the plan view may be gradually reduced in going from the surface of the substrate 110 toward the inside of the concave portion 115. For example, the concave portion 115 may have a cross section of a semi-circular shape or a semi-elliptical shape in the plan view. Further, the concave portion 115 may have a cross section of a semi-circular shape or a semi-elliptical shape in a sectional view.

Since the concave portion 115 has the above shape, electrons can move uniformly regardless of a direction when the electrons move to the front electrode layer 140 near the concave portions 115. Additionally, the concave portion 115 may be formed by laser irradiation, and may have a hemispheric or an inverted pyramidal shape.

The layout of the concave portions 115 may be one of a honeycomb structure or a circular shape in the plan view. As an example, when the layout of the concave portions 115 is a honeycomb structure (that is, the plurality of the concave portions 115 are arranged to constitute the honeycomb structure), the incident light is spread-reflected at the surface. Thus, the reflection at the surface can be reduced or prevented, thereby enhancing the efficiency of the solar cell 100.

Meanwhile, a ratio of a depth H of the concave portion 115 to a maximum width W of the concave portion 115 (that is, a ratio of H/W) may be in a range of about 0.29 to about 0.87. In this instance, the maximum width W of the concave portion 115 is the same of a width of a hole 142 formed at the front electrode layer 140 (that is, formed to correspond to the concave portion 115). The depth H of the concave portion 115 is a vertical length from a bottom surface of the front electrode layer 140 to an upper surface of the emitter layer 120 formed in the concave portion 115 to.

When the ratio of H/W is less than about 0.29, the reflectivity of the sun light may increase. When the ratio of H/W is greater than about 0.87, it is difficult for the concave portion 115 to have the above shape. Thus, the ratio of H/W may be in a range of about 0.29 to about 0.87. When the ratio of H/W is within the above range, the sun light that is incident to the concave portion 115 can be incident to the inside of the solar cell 100 through a number of reflections, such as two reflections. Therefore, the light reflectivity can decrease.

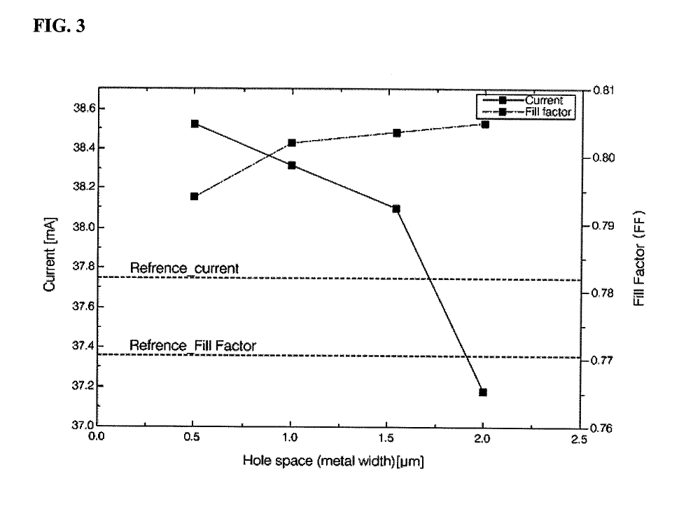

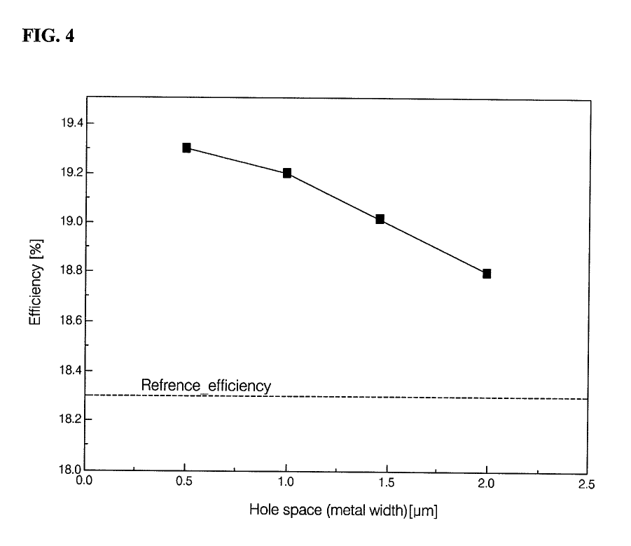

On the other hand, among the plurality of the concave portions 115, two adjacent concave portions adjacent to each other may have a minimum distance D of about 0.5 μm to about 1.5 μm, considering the generated current and the efficiency of the solar cell 100. This will be described later in more detail with reference to FIGS. 3 and 4. In embodiments of the invention, the minimum distance D may be measured between closest edges of the two adjacent concave portions.

As discussed above, because the concave portions 115 are formed at one surface of the substrate 110, the emitter layer 120 and the antireflection layer 130 that are sequentially formed on the substrate 110 may have a shape corresponding to the concave portions 115. The emitter layer 120 may be doped with n-type impurities (for example, an impurity of group 5 elements such as P, As, and Sb). Thus, the emitter layer 120 and the substrate 110 are doped with impurities having opposite conductivities, and a p-n junction is formed at an interface between the substrate 110 and the emitter layer 120. Thus, when the light is irradiated to the p-n junction, electric energy can be generated by the photoelectric effect.

A first portion of the emitter layer 120 formed on the flat surface between the adjacent concave portions 115 and a second portion of the emitter layer 120 formed in the concave portions 115 may have the same thickness. In another embodiment, the respective thicknesses may be different, whereby a thickness of the first portion may be greater than a thickness of the second portion or vice-versa.

The antireflection layer 130 passivates defects at the surface of the emitter layer 120 or in a bulk of the emitter layer 120, and reduces the reflectivity of the sun light that is incident to the front surface of the substrate 110.

Because the defects in the emitter layer 120 are passivated, recombination sites of minority carrier are reduced or eliminated, thereby increasing an open-circuit voltage (Voc) of the solar cell 100. Also, since the reflectivity of the sun light is reduced, the quantity of the sun light reaching the p-n junction increases, thereby increasing a short-circuit current (Isc) of the solar cell 100. Accordingly, the open-circuit voltage (Voc) and the short-circuit current (Isc) of the solar cell 100 are increased by the antireflection layer 130, and thus, the conversion efficiency of the solar cell 100 can be enhanced.

The antireflection layer 130 may include at least one material selected from the group consisting of silicon nitride, silicon nitride including hydrogen, silicon oxide, silicon oxynitride, intrinsic amorphous silicon, MgF₂, ZnS, TiO₂, and CeO₂. Other materials may be used. The antireflection layer 130 may have a one-layered structure, or a multi-layered structure where two or more layers are combined. A first portion of the antireflection layer 130 formed on the flat surface between the adjacent concave portions 115 and a second portion of the antireflection layer 130 formed in the concave portions 115 may have the same or different thicknesses. For example, a thickness of the first portion may be greater than a thickness of the second portion or vice-versa. In an embodiment of the invention, the second portion of the antireflection layer 130 may have a thickness that varies within the concave portions 115. For example, a thickness of the antireflection layer 130 near a top of the concave portions 115 may be thinner than a thickness of the antireflection layer 130 near a bottom of the concave portions 115. In one embodiment of the invention, the thickness of the antireflection layer 130 may increase in going from the top to the bottom of the concave portions 115.

The front electrode layer 140 is formed on the antireflection layer 130 at a flat surface between the concave portions 115, and is connected to the emitter layer 120 by penetrating through the antireflection layer 130.

The reflectivity of the sun light is not sufficiently reduced at the flat surface between the concave portions 115. Thus, by forming the front electrode layer 140 at the flat surface between the concave portions 115, portions of the solar cell 100 where the concave portions 115 are formed and which effectively absorb the sun light can be enlarged.

That is, in a conventional solar cell, concave portions are not formed at portions where finger lines for collecting electrons are formed, or the concave portions are blocked by the finger lines. However, according to embodiments of the invention, the concave portions 115 are formed at an entire portion of the light-incident surface of the solar cell 100, and the front electrode layer 140 is formed only at the flat surface without the concave portions 115 where the light reflectance can be highly reduced or prevented. Thus, the area where the concave portions 115 are formed can be increased as much as the area of the omitted finger lines, and thus, the efficiency of the solar cell 100 can be enhanced.

In addition, the electrons generated by the light irradiation moves along the surface of the emitter layer 120 and are collected by the front electrode layer 140. In embodiments of the invention, the migration length of electrons through the emitter layer 120 to the front electrode layer 140 can decrease.

That is, the front electrode layer 140 according to an embodiment of the invention is connected to the emitter layer 120 by penetrating through the antireflection layer 130 at the flat surface between the concave portions 115. The front electrode layer 140 has a finger matrix shape at the outer periphery of the concave portions 115. Therefore, the number migration routes of the electrons to the front electrode layer 140 can increase, and the current can be distributed. Thus, the migration length of the electrons can decrease, and thus, the decrease of the fill factor of the solar cell 100 due to the long migration length of the electrons can be reduced or prevented.

Finally, the front electrode layer 140 includes one or more holes 142 at the positions corresponding to the concave portions 115, and has an aperture ratio of about 72% to about 98% due to the one or more holes 142. In embodiments of the invention, the aperture ratio refers to a total area of one or more holes 142 relative to a total area of the front electrode layer 140 when the one or more holes 142 are not present.

The width of the hole 142 formed at the front electrode layer 140 is the same as the maximum width W of the concave portion 115. Thus, when the front electrode layer 140 has the aperture ratio less than about 72%, the efficiency of the solar cell 100 may be decreased by the area reduction of the concave portions 115.

On the other hand, when the concave portions 115 have a closed packed structure of the above discussed honeycomb structure, the front electrode layer 140 has a large aperture ratio. However, when the front electrode layer 140 has the aperture ratio greater than about 98%, as the minimum distance D between the concave portions 115 decreases, the resistance of the front electrode layer 140 may increase and the fill factor of the solar cell 100 may be reduced.

Referring to FIG. 1 again, the solar cell 100 according to the embodiment of the invention may include a rear electrode 160 formed on the other surface (i.e., a rear surface or a non-light incident surface) of the substrate 110, and a back surface field layer 165 between the substrate 110 and the rear electrode 160.

The rear electrode 160 may be formed by printing a paste for the rear electrode 160 on the rear surface of the substrate 110 and heat-treating the paste. When the paste for the rear electrode 160 is heat-treated, aluminum of the paste for the rear electrode 160 is diffused through the rear surface of the substrate 110, and the back surface field layer 165 is formed between the rear electrode 160 and the substrate 110.

The back surface field layer 165 reduces or prevents recombination of carriers at the rear surface of the substrate 110, and thereby increases the open-circuit voltage. Accordingly, the efficiency of the solar cell 100 can be enhanced.

Meanwhile, the solar cell 100 according to the embodiment of the invention may further include bus bars 145 connected to the front electrode layer 140. The bus bar 145 is formed on the front electrode layer 140 where the concave portions 115 are not formed, and is not overlapped with the concave portions 115 in a plan view. The bus bar 145 is connected to a ribbon when a solar cell module is manufactured by using a plurality of the solar cells 100. The ribbon may be attached on the bus bar 145 by coating a flux on an upper surface of the bus bar 145, placing the ribbon on the bus bar 145, and firing the flux.

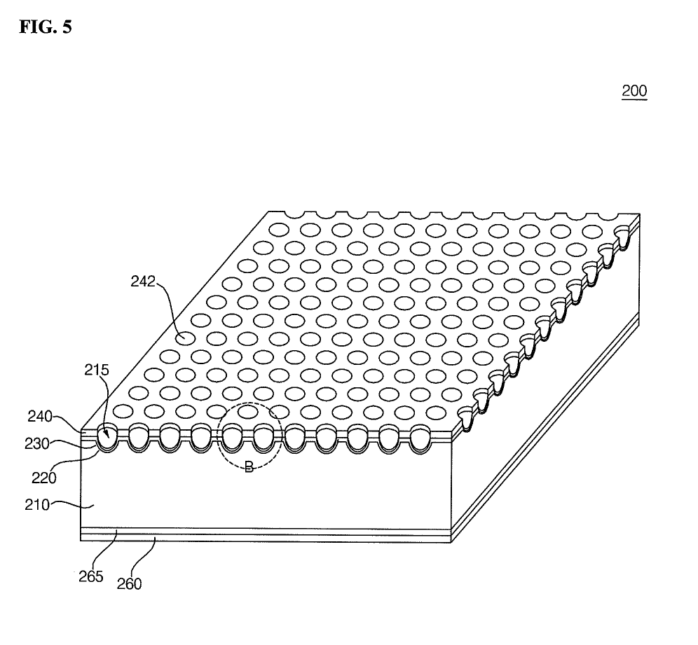

However, the bus bar 145 may be omitted, as shown in FIG. 5. In this instance, when a solar cell module is manufactured by using a plurality of the solar cells 100, isotropic conductive films are attached to a front surface and a rear surface of the solar cells 100 to connect the plurality of the solar cells 100 in series or in parallel.

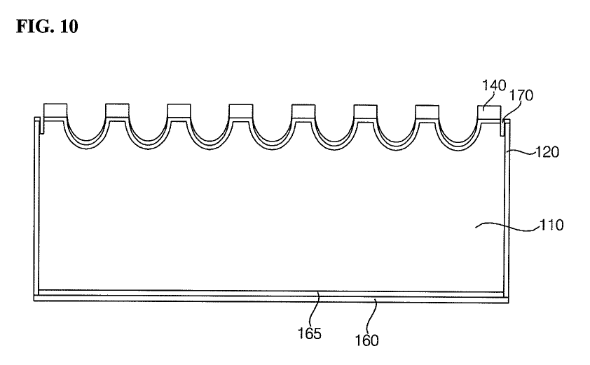

In addition, as in the after-mentioned descriptions regarding FIG. 10, the solar cell according to an embodiment of the invention may include a groove 170 for isolating the front surface and the rear surface of the substrate 110.

FIG. 3 is a graph illustrating current and fill factor according to distance between concave portions according to embodiments of the invention, and FIG. 4 is a graph illustrating efficiency according to distance between concave portions according to embodiments of the invention. In FIG. 3, the fill factor is based on the loss of the resistance, and the current is based on the shadowing area. Also, reference values depicted in FIGS. 3 and 4 are the values of a case with the same concave portions 115 of the embodiment are formed and the finger lines are formed.

As discussed above, among the plurality of the concave portions 115, two adjacent concave portions 115 adjacent to each other may have a minimum distance D of about 0.5 μm to about 1.5 μm. When the minimum distance D is greater than about 1.5 μm, it can be seen that the generated current are largely reduced because the area of the concave portions 115 decreases.

On the other hand, the minimum distance D of two adjacent concave portions 115 is the same as the width of the front electrode layer 140 at the flat surface between the concave portions 115. Thus, when the minimum distance D is less than about 0.5 μm, it can be seen that the fill factor is reduced because the resistance of the front electrode layer 140 increased.

Thus, among the plurality of the concave portions 115, two adjacent concave portions 115 adjacent to each other may have the minimum distance D of about 0.5 μm to about 1.5 μm. In the above range, as shown in FIG. 4, the efficiency of the solar cell 100 is enhanced, compared with the reference values. This is because the migration length of the electrons moving through the emitter layer 120 is reduced, and the shadowing area decreases. That is, the area of the concave portions 115 increases.

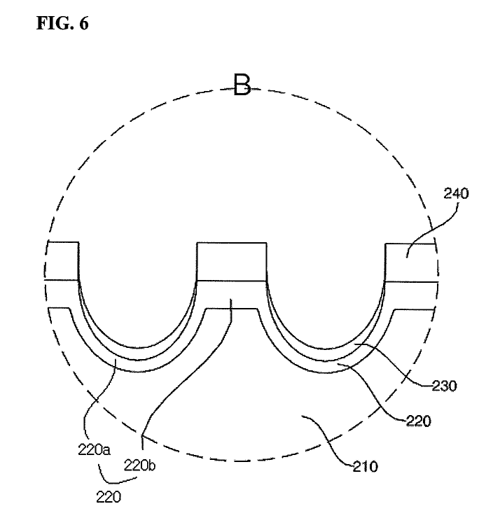

FIG. 5 is a perspective view illustrating a solar cell according to another embodiment of the invention, and FIG. 6 is an enlarged view of a portion B of the solar cell in FIG. 5. Referring to FIGS. 5 and 6, a solar cell 200 according to an embodiment of the invention includes a substrate 210, for example, of a silicon semiconductor, an emitter layer 220, an antireflection layer 230, and a front electrode layer 240. In this instance, the substrate 210 includes a plurality of concave portions 215 formed at a surface thereof. The emitter layer 220 is formed on the surface of the substrate 210 having the concave portions 215. The antireflection layer 230 is formed on the emitter layer 220. The front electrode layer 240 is connected to the emitter layer 220 by penetrating through the antireflection layer 230. Also, the solar cell 200 may include a rear electrode 260 and a back surface field layer 265 between the substrate 210 and the rear electrode 260 at the other surface of the substrate 210.

The substrate 210, the concave portions 215, the antireflection layer 230, the front electrode layer 240, the rear electrode 260, and the back surface field layer 265 are the same as in the descriptions of the embodiment in FIGS. 1 and 2. Thus, a detailed description of the above elements will be omitted.

In the solar cell 200 according to an embodiment of the invention, in order to reduce contact resistance with the front electrode layer 240 and to reduce or prevent an efficiency decrease of the solar cell 200, the emitter layer 220 has a selective emitter structure having a high doping concentration portion at a portion where the front electrode layer 240 is formed, and a low doping concentration portion.

That is, the emitter layer 220 includes a first portion 220a formed on the concave portion 215 to correspond to a hole 242, and a second portion 220b formed on a flat portion where the concave portion 215 is not formed, and connected to the front electrode layer 240. The first portion 220a has a doping concentration smaller than that of the second portion 220b. Since the first portion 220a of the emitter layer 200 formed on the concave portion 215 has a relatively small doping concentration, recombination of carriers at the surface can be reduced.

In addition, because the front electrode layer 240 is not formed on the concave portion 215, a shallow emitter can be formed. Therefore, transmission of the light of blue color having a short wavelength can increase, thereby enhancing the efficiency of the solar cell 200.

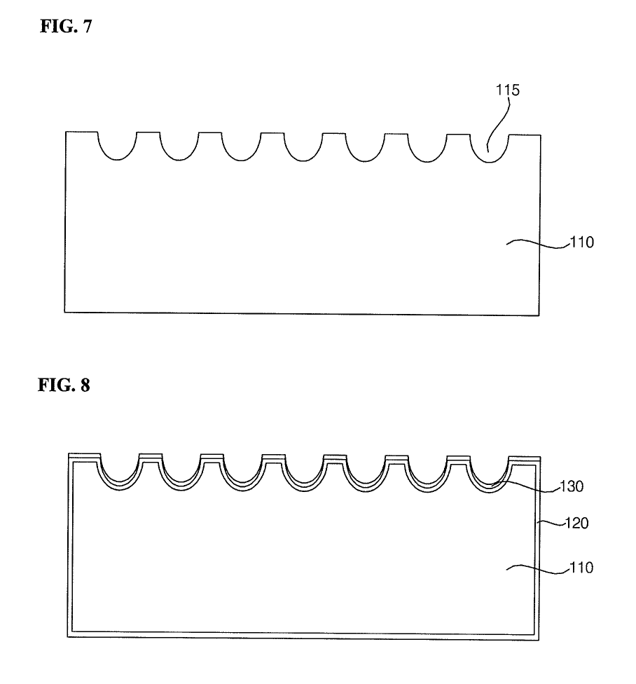

FIGS. 7 to 10 are cross-sectional views illustrating a method for manufacturing a solar cell according to an embodiment of the invention. Accordingly, a method for manufacturing the solar cell according to an embodiment of the invention will be described with reference to FIGS. 7 to 10. First, the concave portions 115 are formed at one surface of the substrate 110. The concave portions 115 may be formed by placing a mask having openings on the substrate 110 and irradiating a laser beam through the openings. The mask may be formed by depositing silicon nitride (SiNx) or other material on the substrate 110, and forming the openings through light exposure and development. The concave portions 115 may have a hemispheric or an inverted pyramidal shape, as well as other shapes. The width and the depth of the concave portion 115 can be adjusted by controlling an intensity of the laser beam.

Next, as shown in FIG. 8, the emitter layer 120 and the antireflection layer 130 are sequentially formed. The emitter layer 120 and the antireflection layer 130 have shapes corresponding to shapes of the concave portions 115. The emitter layer 120 may be formed by doping n-type impurities into the substrate 110 of a p-type through a diffusion method, a spray method, or a printing method, for example.

The antireflection layer 130 may be formed by a vacuum evaporation method, a chemical vapor deposition method, a spin coating method, a screen printing method, or a spray coating method, for example. However, embodiments of the invention are not limited thereto.

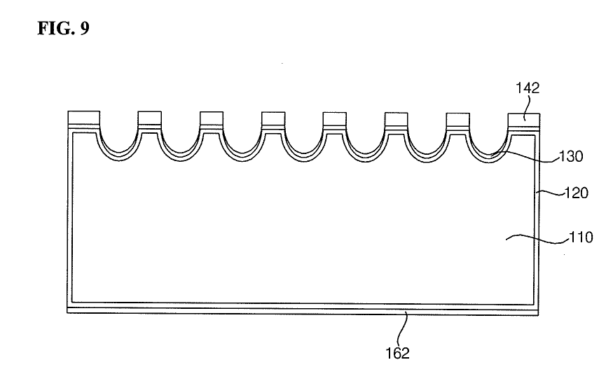

Next, as shown in FIGS. 9 and 10, the front electrode layer 140 and the rear electrode 160 are formed. Specifically, as shown in FIG. 9, in order to form the front electrode layer 140, a paste 142 for a front electrode layer 140 is formed on the flat surface between the concave portions 115.

The paste 142 for the front electrode layer 140 is formed by a stamping or by using a roller. In the stamping, the light incident surface having the concave portions 115 are made to face towards the bottom and towards the paste 142, and the light incident surface having the concave portions 115 is pressed to the paste 142 so that the paste 142 can be stamped on the flat surface between the concave portions 115, like when an ink is coated on a stamp.

In the method using the roller, for example, the paste 142 for the front electrode layer 140 is coated on an entire surface of the cylinder of the roller, and the roller is then contacted with the light incident surface having the concave portions 115 and is rotated while moving the substrate 110 or the roller. Thus, the paste 142 for the front electrode layer 140 can be formed only on the flat surface between the concave portions 115.

The paste 142 for the front electrode layer 140 may include silver, a glass frit, a binder, a solvent, and so on, and may have sufficient viscosity in order to be formed with only on the flat surface between the concave portions 115. The solvent of the paste 142 for the front electrode layer 140 is evaporated and organic materials of the paste 142 for the front electrode layer 140 are burned out during the heat treatment, thereby forming the front electrode layer 140. In this instance, as shown in FIG. 10, by the heat-treatment of the front electrode layer 140 while the silver of the paste 142 for the front electrode layer 140 is liquefied or melted at high temperature and is recrystallized again, the front electrode layer 140 penetrates through the antireflection layer 130 due to the glass frit, and thus, the front electrode layer 140 is connected to the emitter layer 120. In an embodiment of the invention, the front electrode layer 140 may be opaque. In another embodiment of the invention, however, the front electrode layer 140 may be transparent or translucent. Therefore, in the solar cell 100 according to an embodiment of the invention, the front electrode layer 140 can be easily aligned.

The rear electrode 160 may be formed, for example, by printing a paste 162 for the rear electrode 160 having aluminum, quartz silica, and a binder on the other surface (or the rear surface) of the substrate 110 and heat-treating the paste 162 for the rear electrode 160. When the paste 162 for the rear electrode 160 is heat-treated, the back surface field layer 165 may be formed between the rear electrode 160 and the substrate 110 by diffusion of the aluminum constituting the paste 162 for the rear electrode 160 through the rear surface of the substrate 110 as shown in FIG. 10.

On the other hand, the emitter layer 120 may be formed by doping n-type impurities into the substrate 110. In this instance, when the n-type impurities are doped, a side surface of the substrate 110 may also be doped with the n-type impurities. Due to the doping of the side surface, the front surface and the rear surface of the substrate 110 may be electrically connected. Thus, in the solar cell 100 according to an embodiment of the invention, a groove 170 for isolating the emitter layer 120 may be formed by way of a laser isolation to insulate the front surface and the rear surface of the substrate 110.

A method for manufacturing the solar cell 200 having the selective emitter of FIGS. 5 and 6 will be simply described. First, the surface of the substrate 110 is doped with the n-type impurities before forming the concave portion 115 as shown in FIG. 7, and then, the concave portions 115 are formed by using a mask. As discussed above, when the concave portions 115 are formed on the surface of the substrate 110 doped with the impurities, the impurities may remain at the flat surface between the concave portions 115. That is, the impurity-layer where the concave portions 115 are formed may be selectively eliminated by laser irradiation.

Next, as shown in FIG. 8, the emitter layer 120 is formed. As stated above, since the concave portions 115 are formed after the surface of the substrate 110 is doped with the n-type impurities, the flat surface between the concave portions 115 has a high doping concentration due to a sum of the impurities previously doped and the impurities for forming the emitter layer 120.

Next, by performing processes of FIGS. 9 and 10, the front electrode layer 140 is formed. Then, since the flat surface between the concave portions 115 is connected to the front electrode layer 140, the electrode can be easily aligned when the solar cell 100 having the selective emitter.

Certain embodiments of the invention have been described. However, the invention is not limited to the specific embodiments described above, and various modifications of the embodiments are possible by those skilled in the art to which the invention belongs without departing from the scope of the invention defined by the appended claims. Also, modifications of the embodiments should not be understood apart from the principles or scope of the invention.

What is claimed is:

1. A solar cell, comprising:
a silicon semiconductor substrate including a plurality of concave portions formed at a first surface thereof;
an emitter layer formed at the first surface of the silicon semiconductor substrate having the plurality of concave portions;
an antireflection layer formed on the emitter layer; and
a front electrode layer connected to the emitter layer by penetrating through the antireflection layer,
wherein the front electrode layer is formed on a flat surface between the plurality of the concave portions and has a finger matrix shape.

2. The solar cell according to claim 1, wherein the plurality of the concave portions comprises two adjacent concave portions that are adjacent to each other and have a minimum distance of separation of about 0.5 μm to about 1.5 μm.

3. The solar cell according to claim 1, wherein distances from a center to edges of the plurality of concave portions are substantially the same in a plan view.

4. The solar cell according to claim 3, wherein a ratio of a depth to a maximum width of at least one of the plurality of concave portions is in a range of about 0.29 to about 0.87.

5. The solar cell according to claim 1, wherein the plurality of concave portions have a cross section of a semi-circular shape or a semi-elliptical shape.

6. The solar cell according to claim 1, wherein the plurality of the concave portions are arranged to constitute a honeycomb structure.

7. The solar cell according to claim 1, further comprising:
a bus bar connected to the front electrode layer.

8. The solar cell according to claim 7, wherein the bus bar does not overlap with the plurality of the concave portions in a plan view.

9. The solar cell according to claim 1, wherein the front electrode layer is formed on a substantially entire portion of the first surface of the silicon semiconductor substrate except for portions having the plurality of the concave portions.

10. The solar cell according to claim 1, wherein the emitter layer comprises a first portion formed at the plurality of concave portions, and a second portion connected to the front electrode layer and formed where the plurality of concave portions are not formed, and
the first portion has a doping concentration smaller than that of the second portion.

11. The solar cell according to claim 1, further comprising:
a rear electrode formed on a second surface of the silicon semiconductor substrate that is opposite the first surface; and
a back surface field layer between the silicon semiconductor substrate and the rear electrode.

12. A solar cell, comprising:
a silicon semiconductor substrate including a plurality of concave portions formed at a first surface thereof;
an emitter layer formed at the silicon semiconductor substrate, and having a first portion that has a shape corresponding to the plurality of concave portions;
an antireflection layer formed on the emitter layer, and having a portion that has a shape corresponding to the plurality of concave portions; and
a front electrode layer formed on the antireflection layer,
wherein the front electrode layer includes a plurality holes corresponding to the plurality of concave portions, respectively, and is connected to the emitter layer by penetrating through the antireflection layer at a flat surface between the plurality of the concave portions.

13. The solar cell according to claim 12, wherein the emitter layer comprises the first portion formed at the plurality of concave portions, and a second portion connected to the front electrode layer and formed where the plurality of concave portions are not formed, and
the first portion has a doping concentration smaller than that of the second portion.

14. The solar cell according to claim 12, wherein the front electrode layer has an aperture ratio of about 72% to about 98%.

15. The solar cell according to claim 12, wherein distances from a center to edges of the plurality of concave portions are substantially the same in a plan view.

16. The solar cell according to claim 12, further comprising:
a bus bar connected to the front electrode layer.

17. The solar cell according to claim 16, wherein the bus bar does not overlap with the plurality of the concave portions in a plan view.

18. The solar cell according to claim 12, wherein the antireflection layer comprises at least one material selected from the group consisting of silicon nitride (SiNx), silicon oxide (SiO₂), and intrinsic amorphous silicon.

19. The solar cell according to claim 12, further comprising:
a rear electrode formed on a second surface of the silicon semiconductor substrate that is opposite the first surface; and
a back surface field layer between the silicon semiconductor substrate and the rear electrode.

20. The solar cell according to claim 19, further comprising:
a groove that electrically isolates the emitter layer and the back surface field layer of the silicon semiconductor substrate.
